(19) United States
(12) Patent Application Publication
(10) Pub. No.: US 2025/0253834 A1
(43) Pub. Date: Aug. 7, 2025

(54) Single Phase Clock Controlled Master Latch in Flip Flops

(71) Applicant: Taiwan Semiconductor Manufacturing Company, Ltd., Hsinchu (TW)

(72) Inventors: Xing Chao Yin, Hsinchu (TW); I-Wen Wang, Hsinchu (TW); Jia-Hong Gao, Hsinchu (TW); Hui-Zhong Zhuang, Hsinchu (TW); Yung-Chen Chien, Hsinchu (TW); Xiangdong Chen, Hsinchu (TW)

(21) Appl. No.: 18/432,199

(22) Filed: Feb. 5, 2024

(51) Int. Cl. H03K 3/037; H03K 17/30; H03K 19/0185

(52) U.S. Cl. CPC H03K 3/0372; H03K 17/302; H03K 19/01855

(57) ABSTRACT

Systems and methods are provided for a single phase clock controlled flip flop circuit. The circuit comprises a single phase master latch that is configured to receive a data signal and a first timing signal having a first phase. The circuit is configured to generate a master latch output signal based on the data signal and the first timing signal. The single phase master latch is not configured to receive a second timing signal having a second phase. The circuit further includes a slave latch coupled to the single phase master latch. The slave latch is configured to receive the master latch output signal, to store digital data based on the master latch output signal, and to generate a flip flop output signal based on the master latch output signal.

### FIELD

The present disclosure relates to flip flops in digital electronics.

### BACKGROUND

A flip flop is a device used in digital electronics that is used to store and transfer binary data. In some flip flops, the time between receiving data and generating the data at an output node is equal to a setup time (e.g., the time data must be unchanged on the rising edge of a clock signal), plus the amount of time required for the data to arrive at the output node from the rising edge of the clock signal. Some flip flops control both a master circuit and a slave circuit within the flip flop with clock signals having differing phases. In such flip flops, there exists a tradeoff between the setup time and the amount of time required for the data to arrive at the output node from the rising edge of the clock signal. This can lead to slower propagation of data in some flip flops. Furthermore, the design of some flip flops can lead to data racing failures (e.g., racing conditions in which data retrieved by a master circuit is passed to a slave circuit incorrectly before a transmission gate in between is closed).

### BRIEF DESCRIPTION OF THE DRAWINGS

The following detailed description will be better understood when read in conjunction with the appended drawings. For the purpose of illustration, there is shown in the drawings certain embodiments of the present disclosure. It should be understood, however, that the invention is not limited to the precise arrangements and instrumentalities shown. The accompanying drawings, which are incorporated in and constitute a part of this specification, illustrate an implementation of systems and apparatuses consistent with the present invention and, together with the description, serve to explain advantages and principles consistent with the invention.

FIG. 1 depicts a block diagram of a flip flop with a single phase master latch, in accordance with some embodiments.

FIG. 2 depicts a single phase master latch, in accordance with some embodiments.

FIG. 3 depicts a single bit flip flop with a single phase master latch, in accordance with some embodiments.

FIG. 4 depicts a PMOS single phase master latch, in accordance with some embodiments.

FIG. 5 depicts an NMOS single phase master latch, in accordance with some embodiments.

FIG. 6A depicts a single phase master latch, in accordance with some embodiments.

FIG. 6B depicts a timing diagram of a single phase master latch, in accordance with some embodiments.

FIG. 7 depicts a flip flop with a single phase master latch, in accordance with some embodiments.

FIG. 8 depicts a flip flop with a single phase master latch, in accordance with some embodiments.

FIG. 9 depicts a flip flop with a single phase master latch, in accordance with some embodiments.

FIG. 10 depicts a flip flop with a single phase master latch, in accordance with some embodiments.

FIG. 11 depicts a multi-bit flip flop with single phase master latches, in accordance with some embodiments.

FIG. 12 depicts a detailed depiction of a multi-bit flip flop with single phase master latches, in accordance with some embodiments.

FIG. 13 depicts a method of storing data, in accordance with some embodiments.

### DETAILED DESCRIPTION

The following detailed description is provided to assist the reader in gaining a comprehensive understanding of the methods, apparatuses, and/or systems described herein. Accordingly, various changes, modifications, and equivalents of the systems, apparatuses and/or methods described herein will be suggested to those of ordinary skill in the art. Also, descriptions of well-known functions and constructions may be omitted for increased clarity and conciseness.

It is to be understood that the phraseology and terminology employed herein are for the purpose of description and should not be regarded as limiting. For example, the use of a singular term, such as, “a” is not intended as limiting of the number of items. Also the use of relational terms, such as but not limited to, “top,” “bottom,” “left,” “right,” “upper,” “lower,” “down,” “up,” “side,” are used in the description for clarity and are not intended to limit the scope of the invention or the appended claims. Further, it should be understood that any one of the features can be used separately or in combination with other features. Other systems, methods, features, and advantages of the invention will be or become apparent to one with skill in the art upon examination of the detailed description. It is intended that all such additional systems, methods, features, and advantages be included within this description, be within the scope of the present invention, and be protected by the accompanying claims.

As noted above, flip flops are used in digital electronics to store and transfer binary data. In some flip flops, a master latch circuit receives two different timing signals of differing phases. In such flip flops, there exists a tradeoff between the setup time and the amount of time required for the data to arrive at the output node from the rising edge of the clock signal. This can lead to slower propagation of data in some flip flops. Furthermore, the design of some flip flops can lead to data racing failures.

In embodiments, it may be desirable for a flip flop to include a master latch circuit that receives a timing signal that has a single phase. Embodiments disclosed herein involve a master latch circuit that receives a timing signal having a single phase. Such embodiments can mitigate the tradeoff between the setup time and the amount of time required for the data to arrive at the output node from the rising edge of the clock signal, increase propagation time of data, and mitigate data racing failures.

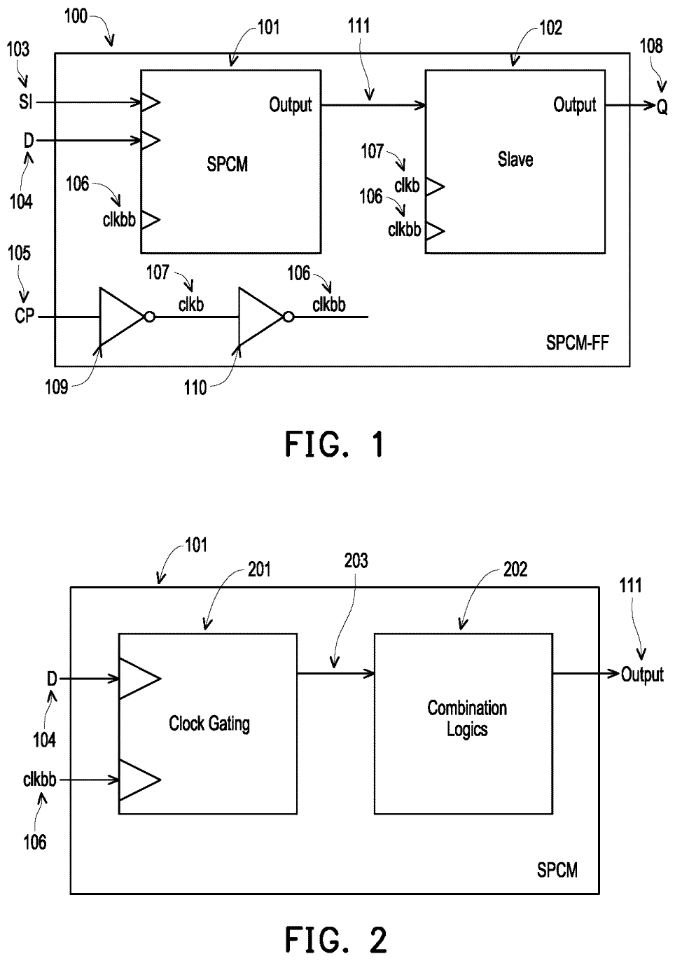

FIG. 1 depicts a block diagram of a flip flop with a single phase master latch, in accordance with some embodiments. In the example shown in FIG. 1, the flip flop 100 includes a single phase master latch 101 and a slave latch 102. The flip flop 100 further includes a first inverter 109 and a second inverter 110 coupled to the first inverter 109. The first inverter 109 receives a clock pulse signal CP 105 and generates an inverted clock signal clkb 107. The second inverter 110 receives the inverted clock signal clkb 107 and generates a double inverted clock signal clkbb 106. The double inverted clock signal clkbb 106 is received at the single phase master latch 101 and the slave latch 102. The inverted clock signal clkb 107 is also received at the slave latch 102. The single phase master latch 101 also receives a data signal D 104 and a serial input signal SI 103. The single phase master latch 101 is configured to store the data signal D 104 during a transition (e.g., from 0 to 1) of the inverted clock signal clkb 107. The data signal D 104 is fixed within the single phase master latch 101. Based on the data signal D 104 and the serial input signal SI 103, the single phase master latch 101 generates a master latch output signal 111. The master latch output signal 111 may be the same value of the data signal D 104 or may be the value of an inverted data signal D 104. The slave latch 102 receives the master latch output signal 111. When the inverted clock signal clkb 107 transitions values again (e.g., from 1 to 0), the master latch output signal 111 is fixed within the slave latch 102. When the master latch output signal 111 is fixed within the slave latch 102, the single phase master latch 101 begins to receive new values of the data signal D 104. Based on the master latch output signal 111, the inverted clock signal clkb 107, and the double inverted clock signal clkbb 106, the slave latch 102 generates a flip flop output signal Q 108. The flip flop output signal Q may be equivalent to the value of the data signal D 104 from a previous clock cycle.

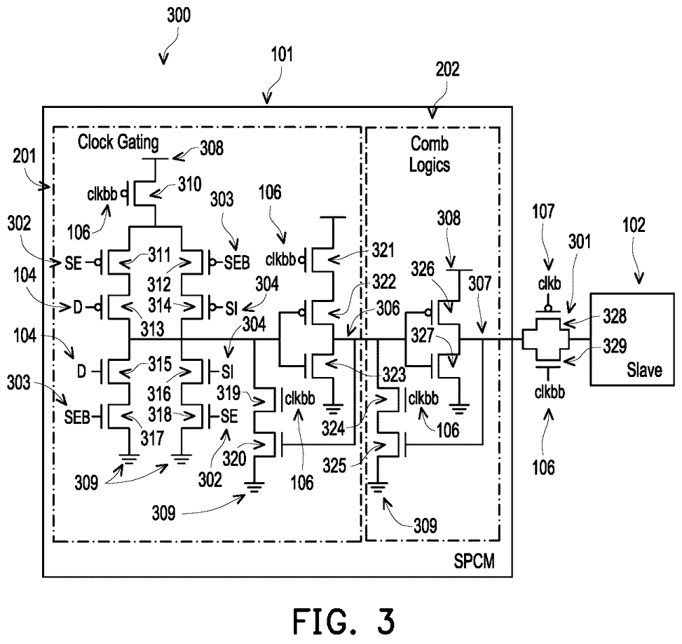

FIG. 2 depicts a single phase master latch, in accordance with some embodiments. In the example shown in FIG. 2, the single phase master latch 101 includes a clock gating circuit 201 and a combinational logic circuit 202. The clock gating circuit 201 receives the data signal D 104 and the double inverted clock signal clkbb 106. Based on the data signal D 104 and the double inverted clock signal clkbb 106, the clock gating circuit 201 generates a gating output signal 203. The combinational logic circuit 202 receives the gating output signal 203. The combinational logic circuit 202 also receives the double inverted clock signal clkbb 106. Based on the gating output signal 203 and the double inverted clock signal clkbb 106, the combinational logic circuit 202 generates a master output signal 111.

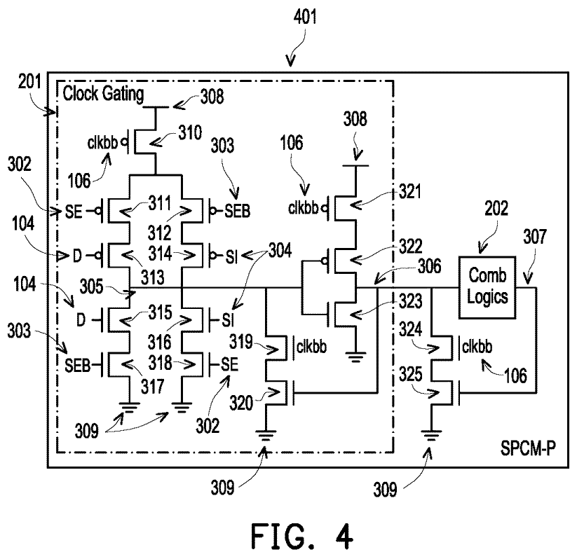

FIG. 3 depicts a single bit flip flop with a single phase master latch, in accordance with some embodiments. In the example shown in FIG. 3, the flip flop 300 includes a single phase master latch 101, a transmission gate 301, and a slave latch 102. The single phase master latch 101 includes a clock gating circuit 201 and a combinational logic circuit 202. Both the clock gating circuit 201 and the combinational logic circuit 202 include a plurality of transistors. The clock gating circuit 201 receives the double inverted clock signal clkbb 106 at a gate terminal of a first PMOS transistor 310 that has a source terminal coupled to an operating voltage node 308. The clock gating circuit 201 receives a serial enable signal 302 at a serial enable PMOS transistor 311. The clock gating circuit 201 also receives the data signal D 104 at a data PMOS transistor 313, a serial input signal SI 304 at a serial input PMOS transistor 314, and an inverted serial enable signal SEB 303 at an inverted serial enable PMOS transistor 312.

Furthermore, the clock gating circuit 201 receives the data signal D 104 at a data NMOS transistor 315, the serial input signal SI 304 at a serial input NMOS transistor, the serial enable signal SE 302 at a serial enable NMOS transistor 318, and the inverted serial enable signal SEB 303 at an inverted serial enable NMOS transistor 317. When the double inverted clock signal clkbb 106 is below a threshold voltage of the first PMOS transistor 310, the first PMOS transistor 310 will turn on and the voltage at the operating voltage node 308 will appear at the drain terminal of the first PMOS transistor 310. Furthermore, if both the data signal D 104 and the serial enable signal SE 302 are also below a threshold voltage level of the data PMOS transistor 313 and the serial enable PMOS transistor 311 (e.g., logic low) when the double inverted clock signal clkbb 106 is sufficiently low, the voltage at the operating voltage node 308 will appear at a first master latch node 305. Additionally or alternatively, if both the inverted serial enable signal SEB 303 and the serial input signal SI 304 are also below a threshold voltage level of the inverted serial enable PMOS transistor 312 and the serial input PMOS transistor 314, respectively, when the double inverted clock signal clkbb 106 is sufficiently low, the voltage at the operating voltage node 308 will appear at the first master latch node 305. If the voltage at the operating voltage node 308 appears at the first master latch node 305, the first master latch node 305 will have a logic high voltage level.

The data NMOS transistor 315 includes a drain terminal coupled to the first master latch node 305. The inverted serial enable NMOS transistor 303 includes a drain terminal coupled to a source terminal of the data NMOS transistor 315. The source terminal of the inverted serial enable NMOS transistor 317 is coupled to a ground node 309. The serial input NMOS transistor 316 includes a drain terminal coupled to the first master latch node 305. The serial enable NMOS transistor 318 includes a drain terminal coupled to a source terminal of the serial input NMOS transistor 316 and a source terminal coupled to the ground node 309. When the data signal D 104 is above a threshold voltage level, the data NMOS transistor 315 turns on. If the inverted serial enable signal SEB 303 is also above a threshold voltage level, the inverted serial enable NMOS transistor 317 will turn on and the voltage at the ground node 309 (e.g., zero volts) will appear at the first master latch node 305. Additionally or alternatively, if both the serial input signal SI 304 and the serial enable signal SE 302 are above a voltage threshold level, both the serial input NMOS transistor 316 and the serial enable NMOS transistor 318 will turn on and the voltage at the ground node 309 will appear at the first master latch node 305. If the voltage at the ground node 309 appears at the first master latch node 305, the first master latch node 305 will have a logic low voltage level.

The clock gating circuit 201 further includes a first NMOS transistor 319 and a second NMOS transistor 320. The first NMOS transistor 319 has a drain terminal coupled to the first master latch node 305. The first NMOS transistor has a gate terminal that receives the double inverted clock signal clkbb 106 and a source terminal that is coupled to a drain terminal of the second NMOS transistor 320. The second NMOS transistor 320 has a source terminal that is coupled to the ground node 309. The clock gating circuit 201 further includes a second PMOS transistor 321 having a source terminal coupled to the operating voltage node 308. The second PMOS transistor 321 has a gate terminal that receives the double inverted clock signal clkbb 106. The second PMOS transistor 321 includes a drain terminal coupled to a source terminal of a third PMOS transistor 322. The third PMOS transistor 322 includes a gate terminal that is coupled to the first master latch node 305. The third PMOS transistor 322 further includes a drain terminal that is coupled to a drain terminal of a third NMOS transistor 323. The third NMOS transistor 323 includes a gate terminal that is coupled to the first master latch node 305 and a source terminal that is coupled to the ground node 309.

The combinational logic circuit 202 includes a fourth PMOS transistor 326 and a fourth NMOS transistor 327. The fourth PMOS transistor 326 includes a source terminal coupled to the operating voltage node 308. A gate terminal of the fourth PMOS transistor 326 is coupled to the second master latch node 306. A drain terminal of the fourth PMOS transistor 326 is coupled to a third master latch node 307 and a drain terminal of the fourth NMOS transistor 327. A gate terminal of the fourth NMOS transistor 327 is coupled to the second master latch node 306. A source terminal of the fourth NMOS transistor 327 is coupled to the ground node 309. The combinational logic circuit 202 further includes a fifth NMOS transistor 324 and a sixth NMOS transistor 325. The fifth NMOS transistor 324 includes a drain terminal that is coupled to the second master latch node 306 and a gate terminal that receives the double inverted clock signal clkbb 106. The fifth NMOS transistor 324 further includes a source terminal that is coupled to a drain terminal of the sixth NMOS transistor 325. The sixth NMOS transistor 325 further includes a gate terminal that is coupled to the third master latch node 307 and a source terminal that is coupled to the ground node 309.

The third master latch node 307 is coupled to the transmission gate 301. The transmission gate 301 includes a PMOS transmission transistor 328 and an NMOS transmission transistor 329. The transmission gate 301 is configured to receive a signal at the third master latch node 307 and transmit the signal to the slave latch 102, as described further below. The slave latch 102 is configured to store data transmitted to it through the transmission gate 301.

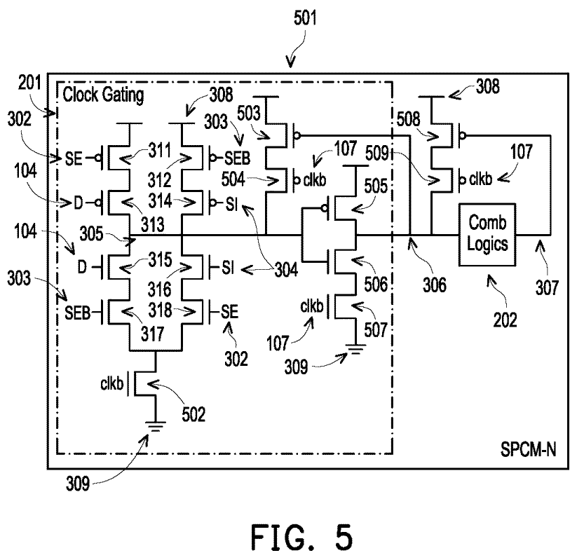

FIG. 4 depicts a PMOS single phase master latch, in accordance with some embodiments. In the example shown in FIG. 4, the PMOS single phase master latch 401 is configured to receive the double inverted clock signal clkbb 106 at the first PMOS transistor 310, the second PMOS transistor 321, the first NMOS transistor 319, and the fifth NMOS transistor 324. The PMOS single phase master latch 401 is utilized in flip flops with an even number of clock inverter stages. It may be advantageous for the clock gating circuit 201 to receive the double inverted clock signal clkbb 106 when there are an even number of clock inverter stages because the double inverted clock signal clkbb 106 includes an additional inverter delay compared with the inverted clock signal clkb 107 (see FIG. 1). Accordingly, the tradeoff between the setup time and the amount of time required for the data to arrive at the output node from the rising edge of the clock signal can be mitigated because the inverted clock signal clkb 107 no longer affects the setup rise time (e.g., the time in which data must be stable prior to an edge of the utilized timing signal). Furthermore, the additional inverter delay can improve the setup rise time by increasing the time in which the data is stable. Additionally, the additional inverter delay can mitigate or eliminate the possibility of data racing failures because the double inverted clock signal clkbb 106 in a multiplexer within the PMOS single phase master latch 401 either begins retrieving the data signal D 104 the same time as the double inverted clock signal clkbb 106 turns off or later than the inverted clock signal 107 clkb 107 at the transmission gate 301 turns off.

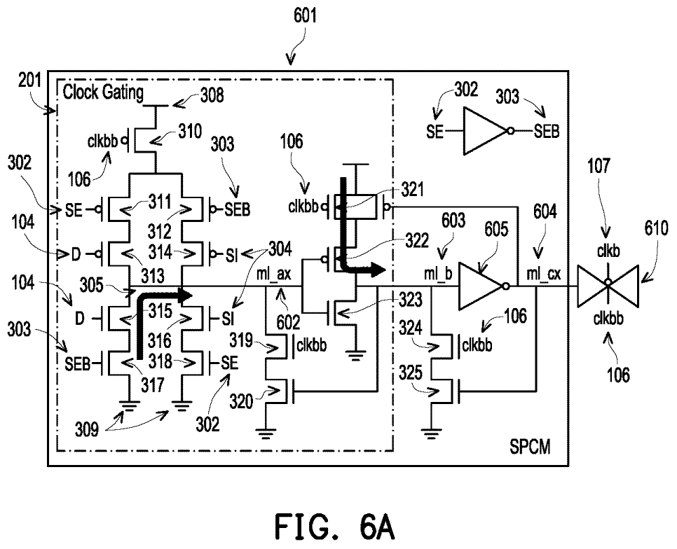

FIG. 5 depicts an NMOS single phase master latch, in accordance with some embodiments. In the example shown in FIG. 4, the NMOS single phase master latch 501 is configured to receive the inverted clock signal clkb 107 at a first NMOS transistor 502, a second PMOS transistor 504, a third NMOS transistor 507, and a fifth PMOS transistor 509. The NMOS single phase master latch 501 is utilized in flip flops with an odd number of clock inverter stages. It may be advantageous for the clock gating circuit 201 to receive the inverted clock signal clkb 107 when there are an odd number of clock inverter stages because the inverted clock signal clkb 107 includes an additional inverter delay compared with the double inverted clock signal clkbb 106 (see FIG. 1). Accordingly, the advantages described with respect to the PMOS single phase master latch 401 in FIG. 4 may be applicable to the NMOS single phase master latch 501 shown in FIG. 5 when flip flops have an odd number of clock inverter stages.

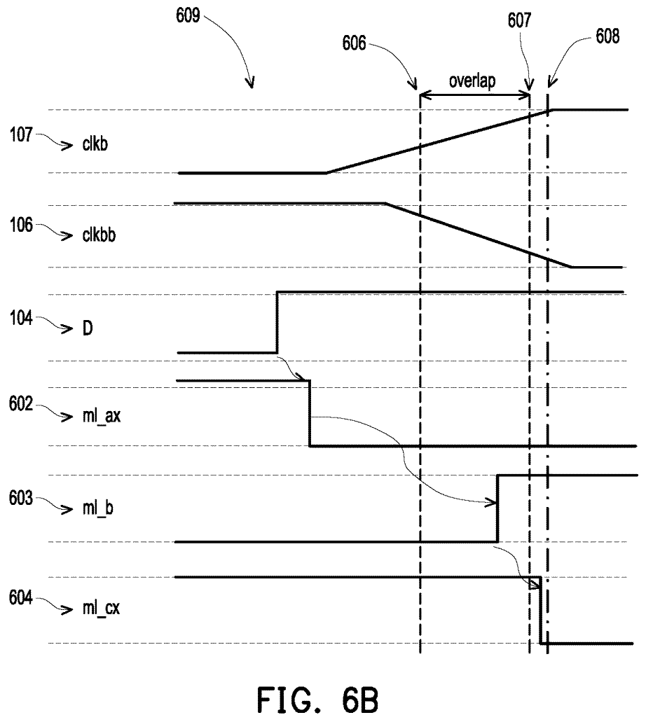

FIG. 6A depicts a single phase master latch, in accordance with some embodiments. FIG. 6B depicts a timing diagram of a single phase master latch, in accordance with some embodiments. The operation of the single phase master latch 601 may be best understood when described in conjunction with the timing diagram 609 of FIG. 6B. In the example shown in FIG. 6A, the data signal D 104 is at logic high (e.g., “1”). When the inverted serial enable signal SEB 303 is also at logic high, both the inverted serial enable NMOS transistor 317 and the data NMOS transistor 315 turn on and the voltage at the ground node 309 appears at the first master latch node 305. Therefore, a first master latch signal ml_ax 602 is at logic low (e.g., “0”). The logic low first master latch signal ml_ax 602 is received at and turns on the third PMOS transistor 322. When the double inverted clock signal clkbb 106 is also at logic low, the second PMOS transistor 321 also turns on and the voltage from the operating voltage node 308 is coupled to the second master latch node 603. Therefore, a second master latch signal ml_bx 603 is at logic high. The second master latch signal ml_bx 603 is received at an inverter 605. The inverter 605 then generates a logic low third master latch signal ml_cx 604. The third master latch signal ml_cx 604 is an output of the single phase master latch 601 and is received at a transmission gate 610.

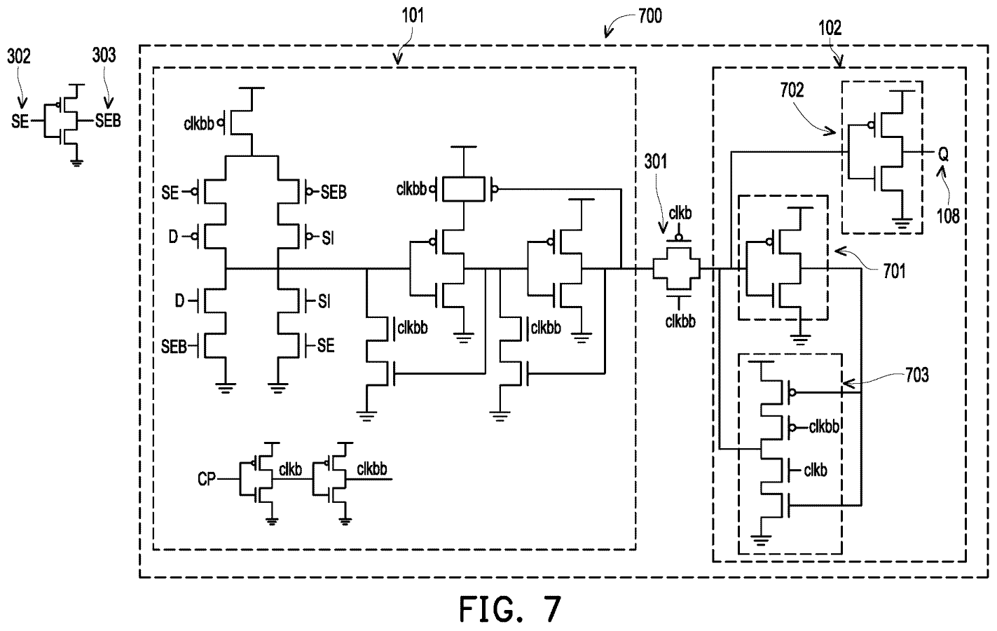

FIG. 7 depicts a flip flop with a single phase master latch, in accordance with some embodiments. In the example shown in FIG. 7, the flip flop 700 includes a single phase master latch 101, a transmission gate 301, and a slave latch 102. The single phase master latch 101 is substantially similar to the PMOS single phase master latch 601 depicted in FIG. 6A. The slave latch 102 includes a first inverter 701, a second inverter 702, and a feedback inverter 703. The slave latch receives an output of the transmission gate (e.g., a slave latch input signal) at the first inverter 701 and the second inverter 702. The second inverter 702 then generates the flip flop output signal 108. The output of the first inverter 701 is coupled to the input of the feedback inverter 703. The output of the feedback inverter 703 is coupled to the output of the transmission gate 301.

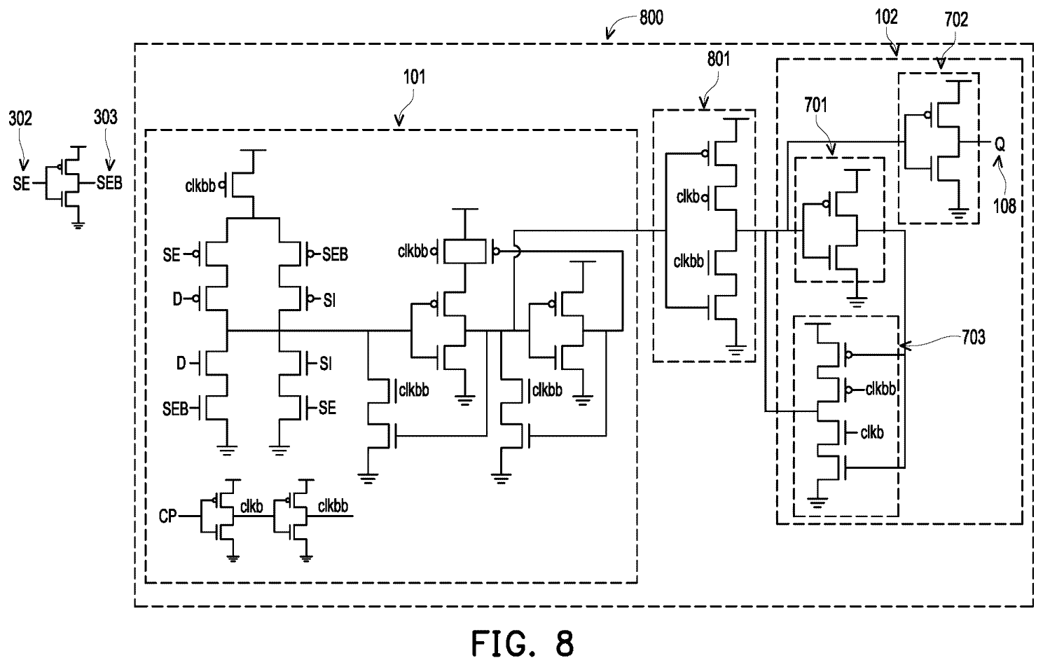

FIG. 8 depicts a flip flop with a single phase master latch, in accordance with some embodiments. In the example shown in FIG. 8, the operation of the single phase master latch 101 and the slave latch 102 may be substantially similar to the operation of the single phase master latch 101 and the slave latch 102 depicted in FIG. 7. FIG. 8 includes a transmission gate 801 having a stacked gate formation. The transmission gate 801 functions as an inverter when the third master latch signal ml_cx 604 (FIG. 6A) and the inverted clock signal clkb 107 are at logic low or when the third master latch signal ml_cx 604 and the double inverted clock signal clkbb 106 are at logic high.

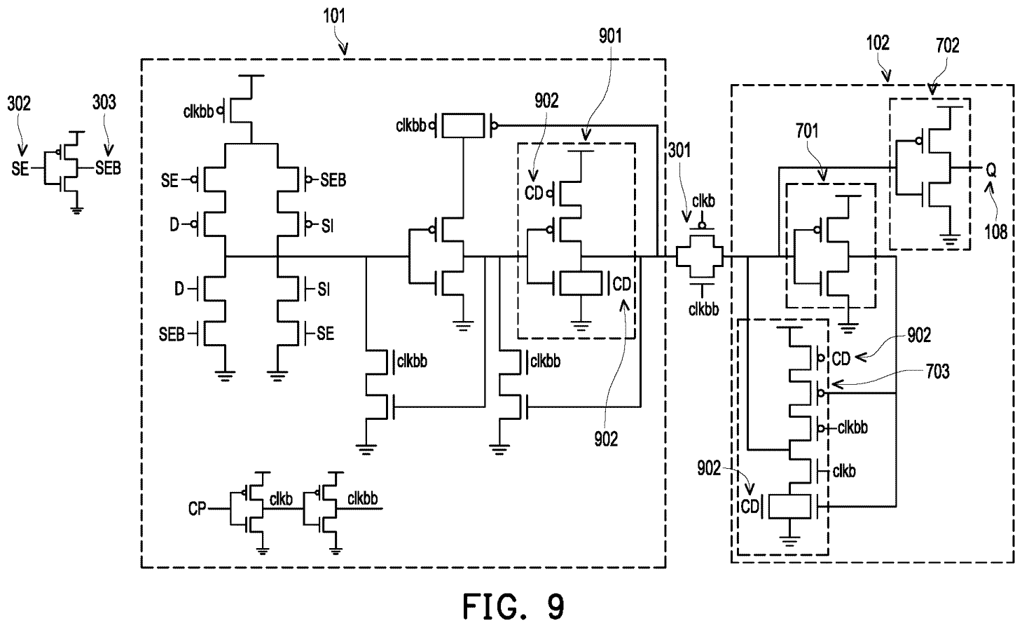

FIG. 9 depicts a flip flop with a single phase master latch, in accordance with some embodiments. In the example shown in FIG. 9, the single phase master latch 101 includes a NAND gate 901. The NAND gate 901 receives as an input a clear data signal CD 902. In addition, the feedback inverter 703 includes an additional PMOS transistor and an additional NMOS transistor that receive the clear data signal CD 902. When the clear data signal CD 902 is received by the NAND gate 901 and the feedback inverter 703, the flip flop output signal Q 108 is reset to a predetermined value (e.g., “1”).

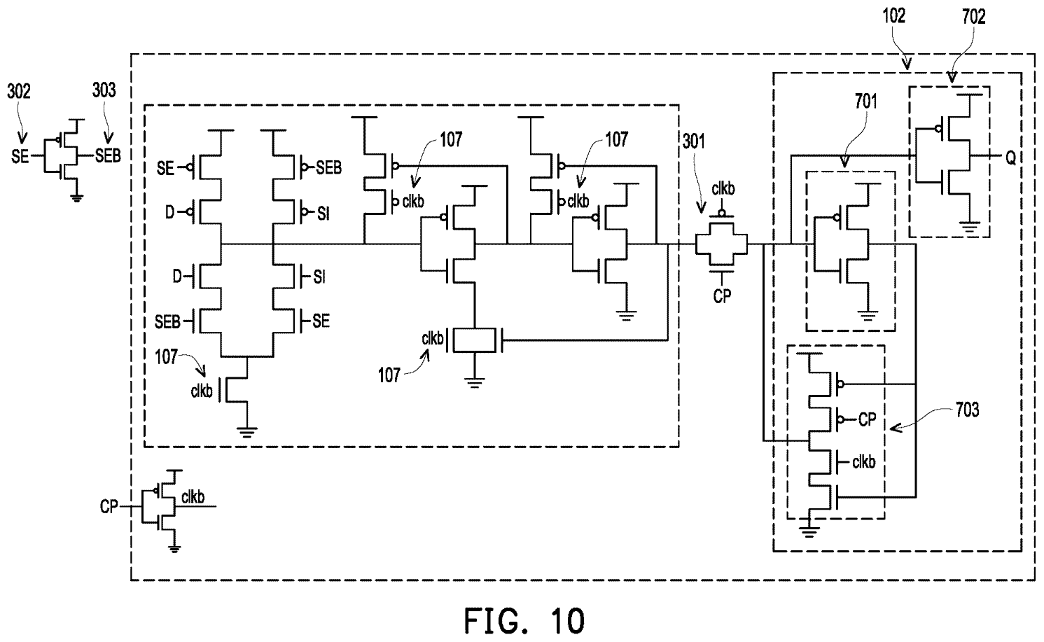

FIG. 10 depicts a flip flop with a single phase master latch, in accordance with some embodiments. In the example shown in FIG. 10, the flip flop 100 includes an NMOS single phase master latch 101. The operation of the NMOS single phase master latch 101 is substantially similar to the operation of the NMOS single phase master latch 501 shown in FIG. 5. As described with respect to FIG. 5, the NMOS single phase master latch 101 is used in flip flops with an odd number of clock inverter stages. The NMOS single phase master latch 101 utilizes the inverted clock signal clkb 107 rather than the double inverted clock signal clkbb 106.

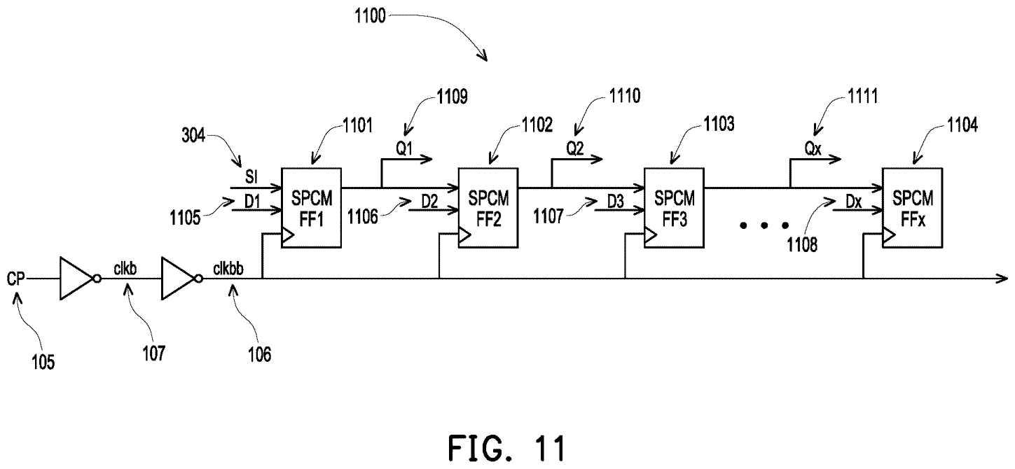

FIG. 11 depicts a multi-bit flip flop with single phase master latches, in accordance with some embodiments. In the example shown in FIG. 11, the multi-bit flip flop 1100 includes a first flip flop 1101, a second flip flop 1102, a third flip flop 1103, and a last flip flop 1104. Each flip flop 1101, 1102, 1103, 1104 within the multi-bit flip flop 1100 receives the double inverted clock signal clkbb 106 as an input. The first flip flop 1101 receives the serial input signal SI 304 and a first data signal D1 1105. Based on the serial input signal SI 304 and the first data signal D1 1105, the first flip flop 1101 generates a first flip flop output signal Q1 1109. The first flip flop output signal Q1 1109 is received as an input to the second flip flop 1102. The second flip flop 1102 also receives a second data signal 1106. Based on the first flip flop output signal Q1 1109 and the second data signal 1106, the second flip flop 1102 generates a second flip flop output signal Q2 1110. The second flip flop output signal Q2 1110 and a third data signal D3 1107 are received by the third flip flop 1103. Outputs of the previous flip flop are received as inputs to subsequent flip flops. Furthermore, each flip flop includes a dedicated data signal. The composition and function of each individual flip flop 1101, 1102, 1103, 1104 may be substantially similar to any of the flip flops with single phase master latches disclosed herein.

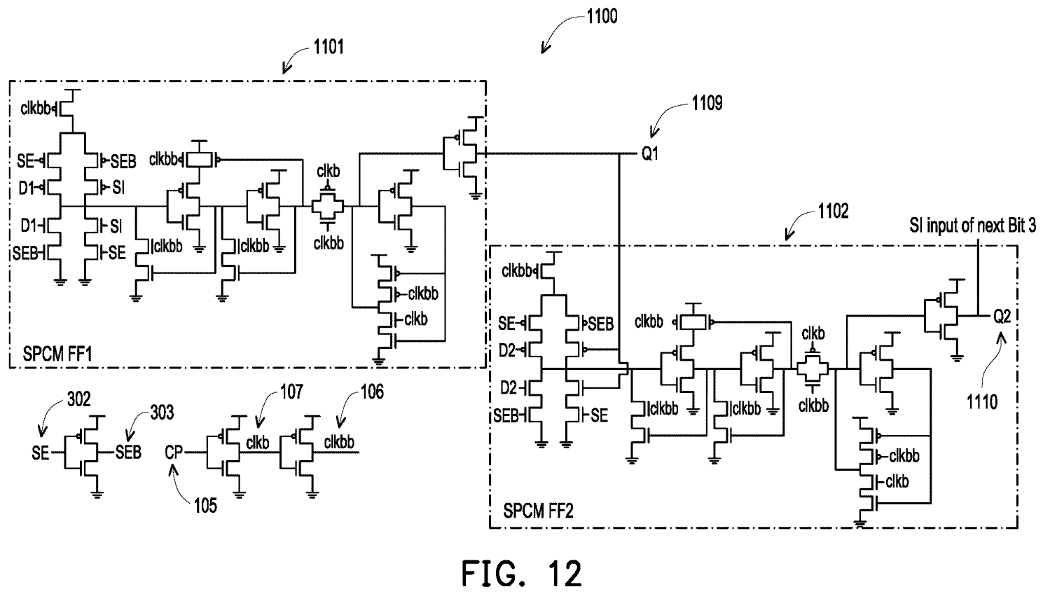

FIG. 12 depicts a detailed depiction of a multi-bit flip flop with single phase master latches, in accordance with some embodiments. In the example shown in FIG. 12, the multi-bit flip flop 1100 includes a first flip flop 1101 and a second flip flop 1102. The first flip flop 1101 and the second flip flop 1102 are connected to each other in series. The operation of each individual flip flop 1101, 1102 may be substantially similar to the operation of the flip flop 700 shown in FIG. 7.

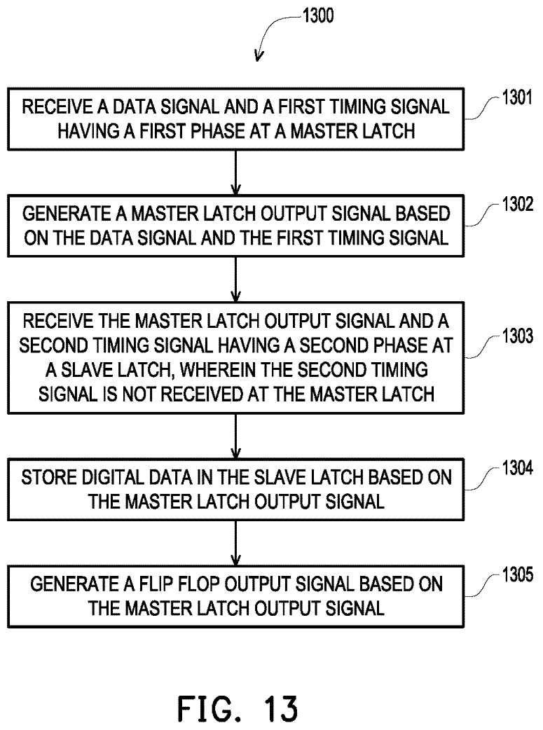

FIG. 13 depicts a method of storing data, in accordance with some embodiments. In the example shown in FIG. 13, the method 1300 includes a first step 1301 of receiving a data signal and a first timing signal having a first phase at a master latch. The first step 1301 is shown in FIG. 4. The clock gating circuit 201 receives the data signal D 104 and the double inverted clock signal clkbb 106. The method 1300 further includes a second step 1302 of generating a master latch output signal based on the data signal and the first timing signal. The second step 1302 is shown in FIG. 1. The single phase master latch 101 generates the master latch output signal 111. The method 1300 further includes a third step 1303 of receiving the master latch output signal and a second timing signal having a second phase at a slave latch. The second timing signal is not received at the master latch. The third step 1303 is shown in FIG. 1. The slave latch 102 receives the master latch output signal 111 and the inverted clock signal clkb 107. As shown in FIG. 1, the inverted clock signal clkb 107 is not received at the master latch 101. The method 1300 further includes a fourth step 1304 of storing digital data in the slave latch based on the master latch output signal. As shown in FIG. 4, digital data is stored at the third master latch node 307. The method 1300 further includes a fifth step 1305 of generating a flip flop output signal based on the master latch output signal. As shown in FIG. 1, the flip flop 100 generates the flip flop output signal Q 108.

Systems and methods are described herein. In one example, a circuit comprises a single phase master latch that is configured to receive a data signal and a first timing signal having a first phase. The circuit is configured to generate a master latch output signal based on the data signal and the first timing signal. The single phase master latch is not configured to receive a second timing signal having a second phase. The circuit further includes a slave latch coupled to the single phase master latch. The slave latch is configured to receive the master latch output signal and a second timing signal having a second phase, to store digital data based on the master latch output signal, and to generate a flip flop output signal based on the master latch output signal.

In another example, a master latch circuit comprises a clock gating circuit that includes a plurality of clock gating transistors. The clock gating circuit is configured to receive a first timing signal having a first phase and a data signal and to generate a clock gating output signal based on the first timing signal and the data signal. The master latch circuit further includes a combinational logics circuit coupled to the clock gating circuit. The combinational logics circuit is configured to receive the clock gating output signal and the first timing signal. The clock gating circuit is further configured to store the clock gating output signal and invert the clock gating output signal.

In another example, a method of storing data includes receiving a data signal and a first timing signal having a first phase at a master latch. The method further includes generating a master latch output signal based on the data signal and the first timing signal. The method further includes receiving the master latch output signal and a second timing signal having a second phase at a slave latch. The second timing signal is not received at the master latch. The method further includes storing digital data in the slave latch based on the master latch output signal. The method further includes generating a flip flop output signal based on the master latch output signal.

It will be appreciated by those skilled in the art that changes could be made to the embodiments described above without departing from the broad inventive concept thereof. It is understood, therefore, that the invention disclosed herein is not limited to the particular embodiments disclosed, and is intended to cover modifications within the spirit and scope of the present invention.

What is claimed is:

1. A circuit comprising:
a master latch configured to receive a data signal and a first timing signal having a first phase and to generate a master latch output signal based on the data signal and the first timing signal; and
a slave latch coupled to the single phase master latch, the slave latch configured to receive the master latch output signal and a second timing signal having a second phase, to store digital data based on the master latch output signal, and to generate a flip flop output signal based on the master latch output signal.

2. The circuit of claim 1, further comprising a transmission gate coupled to the single phase master latch and the slave latch, the transmission gate configured to transfer the master latch output signal from the single phase master latch to the slave latch.

3. The circuit of claim 1, wherein the master latch does not receive the second timing signal.

4. The circuit of claim 1, wherein the master latch is a single phase master latch that receives a single timing signal having a single phase.

5. The circuit of claim 1, wherein the single phase master latch is further configured to receive a serial input signal.

6. The circuit of claim 1, wherein the first timing signal is a double inverted clock signal.

7. The circuit of claim 6, wherein the single phase master latch is a PMOS single phase master latch.

8. The circuit of claim 1, wherein the first timing signal is an inverted clock signal.

9. The circuit of claim 8, wherein the single phase master latch is an NMOS single phase master latch.

10. A master latch circuit comprising:
a clock gating circuit comprising a plurality of clock gating transistors, the clock gating circuit configured to receive a first timing signal having a first phase and a data signal and to generate a clock gating output signal based on the first timing signal and the data signal; and
a combinational logic circuit coupled to the clock gating circuit, the combinational logic circuit configured to receive the clock gating output signal and the first timing signal, the clock gating circuit further configured to store the clock gating output signal and invert the clock gating output signal.

11. The master latch circuit of claim 10, wherein the master latch is a single phase master latch that receives a single timing signal having a single phase.

12. The master latch circuit of claim 10, wherein the first timing signal is a double inverted clock signal.

13. The master latch circuit of claim 12, wherein the second timing signal is an inverted clock signal.

14. The master latch circuit of claim 11, wherein the clock gating circuit receives the first timing signal at a plurality of PMOS transistors.

15. The master latch circuit of claim 11, wherein the clock gating circuit receives the first timing signal at a plurality of NMOS transistors.

16. A method of storing data comprising:
receiving a data signal and a first timing signal having a first phase at a master latch;
generating a master latch output signal based on the data signal and the first timing signal;
receiving the master latch output signal and a second timing signal having a second phase at a slave latch, wherein the second timing signal is not received at the master latch;
storing digital data in the slave latch based on the master latch output signal; and
generating a flip flop output signal based on the master latch output signal.

17. The method of claim 16, further comprising receiving the first timing signal at the slave latch.

18. The method of claim 16, wherein the first timing signal is a double inverted clock signal.

19. The method of claim 18, wherein the second timing signal is an inverted clock signal.

20. The method of claim 19, wherein the master latch includes a plurality of transistors.
